(19) United States
(12) Patent Application Publication
(10) Pub. No.: US 2020/0185368 A1
(43) Pub. Date: Jun. 11, 2020

(54) LED DISPLAY DEVICE AND METHOD FOR MANUFACTURING SAME

(71) Applicant: Seok Min HWANG, Suwon-si (KR)

(72) Inventors: Il Woo PARK, Suwon-si (KR); Seok Min HWANG, Suwon-si (KR)

(21) Appl. No.: 16/792,238

(22) Filed: Feb. 15, 2020

Related U.S. Application Data
(63) Continuation of application No. PCT/KR2017/015449, filed on Dec. 26, 2017.

(51) Int. Cl. H01L 25/16; H01L 33/00; H01L 33/38; H01L 27/12; H01L 33/62; H01L 33/44; H01L 33/32

(52) U.S. Cl. CPC H01L 25/167; H01L 33/0079; H01L 33/38; H01L 27/1262; H01L 33/62; H01L 2933/0025; H01L 33/007; H01L 33/32; H01L 2933/0016; H01L 2933/0066; H01L 33/44

(57) ABSTRACT

The present invention relates to an LED display device and a method for manufacturing the same. A manufacturing method, according to one embodiment of the present invention, comprises the steps of: growing a semiconductor layer on a growth substrate; forming an LED element in an asymmetrical shape from which the semiconductor layer is separated; separating the LED element from the growth substrate; forming a bonding electrode, to which the LED element is bonded, on a display substrate comprising a TFT; forming a groove by patterning the display substrate in the same shape as the LED element formed asymmetrically; seating the LED element in a pattern having the groove in the same shape as the LED element by means of a physical force; and electrically connecting by the bonding electrode of the display substrate or an adhesive conductive material formed on a bonding electrode of the LED element.

### TECHNICAL FIELD

The present invention relates to a display device including a micro-light emitting diode (LED) and a method for manufacturing the same, and more particularly, to a manufacturing method capable of implementing a full-color LED display device by allowing a micro-LED element of a micrometer scale to constitute a unit pixel, and capable of efficiently die-bonding millions of LED elements or more onto a substrate.

### BACKGROUND ART

A light emitting diode (LED) is a light emitting semiconductor element that converts electrical energy into light energy, and has a heterojunction structure including a p-type semiconductor in which holes are majority carriers and an n-type semiconductor in which electrons are majority carriers. The majority carriers are recombined in an active layer while moving in opposite directions by an applied voltage so as to emit excitation energy in the form of photons. At this time, wavelengths of the photons emitted are determined by an inherent energy gap of the active layer.

In general, a light emitting phenomenon may be observed in a compound semiconductor having a direct energy band. The first light emitting phenomenon in a semiconductor was observed in an SiC material having an indirect energy band in 1923. However, SiC having the indirect energy band has very low efficiency, so that only a light emitting phenomenon was observed. The first practical LED is a red LED using GaAsP and developed by GE in 1962, which has been mass-produced in earnest since 1969 by Monsanto Company. A high-brightness red LED using an AlGaAs material was developed in 1980, so that LED applications at a level of indicators began to expand into sign, signal, and display fields. In addition, an ultra-high brightness red LED using an InGaAlP material was developed in 1992, so that the application fields began to expand.

Nitride-based semiconductors have been actively developed, in which Professor Agasaki announced a light emitting phenomenon in a GaN metal insulator semiconductor (MIS) structure using a low-temperature AlN buffer in 1986, and Shuji Nakamura of Nichia Corporation in Japan applied a low-temperature GaN buffer layer and succeeded in fusing a high-quality single crystal GaN nitride semiconductor in 1993. Such LED semiconductors have high light conversion efficiency, which leads to very low energy consumption, a semi-permanent lifespan, and environment-friendly characteristics, so that the LED semiconductors are called as “Green materials—the revolution of light”. Recently, as the compound semiconductor technology develops, high-brightness red, orange, green, blue, and white LEDs have been developed.

The LEDs have various applications, in which the LEDs have been sequentially developed from a blue LED for a keypad to an outdoor electronic display board, a back light unit (BLU) for an LCD TV, a head lamp for an automobile, and an LED lighting device. Recently, researches are being actively conducted to develop a real LED TV by using the LED itself as a pixel of a display device rather than allowing the LED to serve as the BLU.

As an example in which the LED itself serves as a pixel in a display device, there is an already commercially available display device for an outdoor electronic display board, which is a product that can be encountered in everyday life. In this case, LED elements of three primary colors of blue, green, and red are mounted in one package, and tens of thousands to hundreds of thousands of such LED packages are mounted on a supersized substrate so as to be implemented as a display device.

The reason why such a display device implemented as described above is not applied to a TV-sized or monitor-sized display device is that the LED package has a size of about 2×2 mm², which is too large for a TV pixel. Even if the display device is manufactured in a large size, when considering that a unit price of the LED package is about 50 to 100 Won, a price of an LED package light source will be 100 million to 200 million Won upon manufacture of an FHD (1920×1080) display device, so that the price becomes too expensive and far from a price of a household appliance.

When using a micrometer-sized LED element having a size corresponding to about 1/1,000 to 1/10,000 of a size of a typical LED element installed in a LCD TV or a lighting device, the micrometer-sized LED element may be smaller than a size of a pixel of an LCD or OLED, and a price of a light source using the LED element may be significantly low upon the manufacture of the FHD display device as compared with the case where the LED package is used.

Recently, there has been a movement in the industry to apply LEDs as pixels for a wristwatch display device and a large display device. The reason is that the LED is 4 to 5 times more energy efficient than the LCD or OLED, so that the LED is suitable for the wristwatch display device having small battery capacity and has advantages compared to existing display devices, such as a high contrast ratio, ultra-high contrast, a wide viewing angle up to 180 degrees, a maximum brightness of 1,000 nits, 10-bit color gamut (140% based on sRGB), high dynamic range (HDR), and a long lifespan. In addition, the LEDs may be applied to a flexible display device.

Full-color display devices using such small-sized blue, green, and red LED elements are being developed by several research groups. The technologies for the full-color display devices include a scheme of allowing mass transfer of LED elements by using an electrostatic head, and a scheme of attaching a large amount of LED elements to polydimethylsiloxane (PDMS) to transfer the LED elements to a desired substrate. Even though such technologies have been developed for two to five years or more, commercialization of the technologies for a display device has been delayed. The reason seems to be that: the development of micrometer-sized LED elements is required; the LED elements may be destroyed by electrostatic discharge (ESD) when the electrostatic head is used to move and bond millions of LED elements or more to a display panel within a short time; and in the case of performing the transfer using the PDMS, which is a polymer material having elasticity, the development of a technology for aligning the micrometer-sized LED elements with high precision while maintaining equidistant intervals has encountered difficulties.

The present invention proposes a method form manufacturing a full-color LED display device, in which an LED element is individually separated from a growth substrate in a scheme differentiated from an existing scheme, and the LED element is seated and bonded onto a predetermined position of a display substrate by applying a physical force without being attached to any support substrate, tape, or PDMS.

[Document 1] U.S. Pat. No. 8,646,505 B2 (Andreas Bibl) 2014. Feb. 11.

[Document 2] Hoon-sik Kim. Unusual strategies for using indium gallium nitride grown on silicon (111) for solid-state lighting, 10072-10077, PNAS, Jun. 21, 2011, vol. 108, no. 25

### DISCLOSURE

### Technical Problem

A conventional die-bonding scheme designed to manufacture an LED display device includes: a manufacturing scheme for transferring a GaN layer, that is, an LED element grown on a silicon substrate to GaN Layer PDMS by removing the Si substrate used for growth by using an etching rate difference between Si(111) and Si(110) surfaces; a scheme of wafer-bonding a GaN layer, that is, an LED element grown on a sapphire substrate to an Si substrate, which is a substrate different from the sapphire substrate, removing a bonding interface with an acid solution, and transferring the separated LED element to another substrate by using PDMS; and a scheme of preparing a vertical LED element and transferring the vertical LED element by using an electrostatic head.

The above-described three technologies are technologies for transferring an LED element by picking up the LED element and moving the LED element to a substrate uniformly at a predetermined interval. The production capacity is expected to be better than a case of die-bonding the LED element by moving the LED element one by one. However, a technology for repeatedly and precisely performing micrometer-scale alignment is required. The transfer scheme using static electricity has an issue that the LED element may be damaged by the static electricity, and the electrostatic head has to be precisely operated to die-bond numerous chips stably and precisely.

A person who has actually manufactured an element may predict that there may be some problems with the above technologies. For example, in the case of the GaN LED element grown on sapphire, if there is a crystal defect caused by abnormal growth of a crystal, basically, a leakage current may be represented in an abnormal growth portion. Such an abnormal growth portion representing the leakage current may cause the crystal defect due to a growth temperature condition when a semiconductor is grown in a metal organic chemical vapor deposition (MOCVD) facility, a flow rate of a semiconductor growth gas, a temperature difference within a growth substrate, lattice mismatch between the growth substrate and a semiconductor layer, contamination of the growth substrate, and the like. In addition, due to particles and the like, which accumulate inside an MOCVD reactor and then fall off, the crystal defect and particles may be found on random positions on the growth substrate while the semiconductor layer is being grown.

The above crystal defect may not be completely removed due to a size and a growth condition of the growth substrate and an environment, so that the crystal defect is always found in practice when mass production is performed by general LED companies. When an LED element having a size of 1×1 mm² is formed of GaN grown on a typical 4-inch wafer, about 3% of the LED elements formed on the wafer may represent the leakage current due to the crystal defect.

When the LED elements are uniformly arranged and transferred, defective LED elements may be transferred together with good LED elements, which may cause defective pixels in an LED display device. In this case, moving dozens to millions of LED elements or more by the transfer scheme will always cause the defective pixels, and it will be very difficult to repair the LED elements after the die-bonding process is completed. When a substrate on which GaN is perfectly grown is prepared, perfect fabrication is performed, and perfect transfer is performed, the display device may be well manufactured without the defective pixels. However, when the transfer scheme is used to a GaN wafer having basic growth defects, the die-bonding may not be performed as intended. Therefore, the transfer scheme unavoidably causes the defective pixels, which requires repair, so that the manufacture of the display device may become very difficult.

Therefore, an object of the present invention is to provide a method for manufacturing an LED element and a display device necessary for efficiently die-bonding millions of good blue, green, and red LED elements or more to a substrate through a die-bonding scheme of a new concept.

### Technical Solution

Hereinafter, exemplary embodiments of the present invention will be described with reference to the accompanying drawings. However, the embodiments of the present invention may be modified in various other forms, and the scope of the present invention is not limited to the embodiments described below.

In addition, the embodiments of the present invention are provided to give a more comprehensive explanation of the present invention to those of ordinary skill in the art. Therefore, shapes and sizes of components in the drawings may be exaggerated to provide a more clear description, and components represented by the same reference numerals in the drawings are the same components. In the present disclosure, a ‘bonding electrode side’ of an LED element refers to a surface on which a bonding electrode is formed, and an ‘opposite side of the bonding electrode side’ refers to a top surface of the LED element which is visually recognized when the LED element is bonded to a display substrate.

To achieve the objects described above, according to the present invention, there is provided a method of manufacturing an LED element, the method including: forming an LED element layer on a growth substrate formed of a conductive insulating semiconductor material and the like such as sapphire, Si, SiC, MgAl₂O₄, MgO, LiAlO₂, LiGaO₂, GaN, glass, and GaAs, wherein the LED element layer is a light emitting structure including a first-conductivity type semiconductor layer, a second-conductivity type semiconductor layer, and an active layer disposed between the first-conductivity type semiconductor layer and the second-conductivity type semiconductor layer.

The method may further include: etching a portion of the formed LED element layer to a level of the first-conductivity type semiconductor layer; forming a second semiconductor layer and an ohmic contact layer; anisotropically etching the LED element layer until the growth substrate is exposed; forming an insulating film of SiO₂, Si₃N₄, or the like on an entire surface including the exposed LED element layer; etching a portion of the insulating film to a level of the ohmic contact layer of the second semiconductor layer and a first semiconductor layer; and forming a bonding electrode electrically connected to the ohmic contact layer of the second semiconductor layer and the first semiconductor layer, wherein the bonding electrode is formed of a material including at least one of a material such as Cu, Ni, Sn, Pd, Pt, Cr, Ag, Ti, Rh, Al, and Au, and an alloy thereof. In addition, the method may further include: coating a photoresist (PR) onto the LED element of the growth substrate, and baking the PR; applying wax to a PR surface, and wafer-bonding the PR surface to a substrate different from the growth substrate; separating sapphire and the LED element from each other by using a laser; performing dry or wet etching on an insulating film in which LED elements are connected to each other between a separated GaN surface and an exposed insulating film; washing a Ga drop by using HCl; anisotropically etching the GaN surface by using KOH; allowing the PR and the wax to be melted by using a photoresist remover (PR remover); removing the PR remover by using isopropyl alcohol (IPA); and performing washing by using deionized water (DI water).

The LED element formed through the anisotropically etching of the LED element layer until the growth substrate is exposed may have an asymmetric shape when viewed from an LED element electrode side or an opposite side thereof.

In order to die-bond the LED element to the display substrate, a space for placing the LED element is required in the display substrate. The display substrate may include a second bonding electrode and a first bonding electrode, wherein the bonding electrode may be formed of a material including at least one of a material such as Cu, Ni, Sn, Pd, Pt, Cr, Ag, Ti, Rh, Al, and Au, and an alloy thereof.

A groove having the same shape as the LED element may be formed. The groove may be sized to include a suitable clearance so that the LED element may be inserted into the groove. In addition, a depth of the groove may be maintained to be shallower than or equal to a height of the LED element. Since the LED element has the asymmetric shape, the LED element may be aligned in one direction when the LED element is inserted into the groove. In detail, the second bonding electrode (17) and the first bonding electrode (16) of each LED element may be uniformly aligned with a second electrode (42) and a first electrode (41) of the display, respectively, and the LED element may not be inserted upside down or sideways.

The groove may be formed on the display substrate through a photolithography process by using one of materials including a photoresist, a photoresist dry film, and a photosensitive material having excellent thermal stability at a high temperature (100 to 300° C.), or may be formed on the display substrate by coating glass, a polymer, a polymer material, or the like onto the display substrate, and forming and etching a pattern by using the photolithography process.

Instead of the groove described above, the LED element may be aligned by aligning a mask, which has a hole having the same shape as the LED element, on the display substrate. A flux may be applied to the bonding electrode of the display substrate before aligning the mask on the substrate.

Since a defective LED element has to be prevented from being bonded to the display substrate, the defective LED element may be screened out in advance through electrical or optical inspection. Only a good LED element obtained through the screening process as described above may be bonded to the display substrate.

The display substrate formed as described above may be fixedly placed on a mechanical device capable of applying a physical force such as vibration, rotation, and tilting. Only the good LED element may be distributed on the display substrate, and the physical force may be applied by the mechanical device. As a result, the LED elements may be aligned and inserted in grooves, respectively.

In order to implement a full-color LED display device, grooves having the same shapes as opposite sides of electrode sides of blue, green, and red LED elements which have mutually different shapes may be formed on the display substrate on which a thin film transistor (TFT) is formed. The groove may have a clearance to allow the LED element to be inserted into the groove. As a result, the blue, green, and red LED elements may be aligned and inserted in the grooves that fit the shapes of the LED elements, respectively. In this case, a shape of each LED element viewed from an electrode side of the LED element and a shape of each LED element viewed from an opposite side of the electrode side have to be different from each other.

### Advantageous Effects

Therefore, an object of the present invention is to provide a manufacturing method for performing die-bonding by preparing a specific type of LED element, forming a groove having the same shape as the element in a display substrate, and seating the LED element in the groove by a physical force within a short time, without requiring a device capable of aligning millions of LED elements or more with high precision through a die-bonding scheme of a new concept.

The blue, green, and red LED elements which become pixels can be simultaneously die-bonded to the full-color LED display device, so that the die-bonding can be performed within a short time.

Unlike the transfer scheme, individual LED elements having defective electrical and optical characteristics and a defective appearance are screened out before the die-bonding, and the remaining LED elements are assembled to the display substrate, so that the occurrence of defective pixels can be minimized.

### DESCRIPTION OF DRAWINGS

FIG. 1 is a sectional view showing a structure in which an LED element and a growth substrate 10 are attached to each other.

FIG. 2 is a sectional view showing the LED element.

FIGS. 3A, 3B, and 3C are perspective views showing a symmetric LED element.

FIGS. 4A, 4B, and 4C are sectional views showing a state in which the symmetric LED element is inserted into a groove formed in a display substrate.

FIGS. 5A, 5B, 5C, 5D, 5E, 5F, 5G, and 5H are plan views showing axisymmetric shapes.

FIGS. 6A and 6B are plan views showing point-symmetric shapes.

FIGS. 7A, 7B, 7C, 7D, 7E, 7F, 7G, and 7H are plan views showing asymmetric shapes.

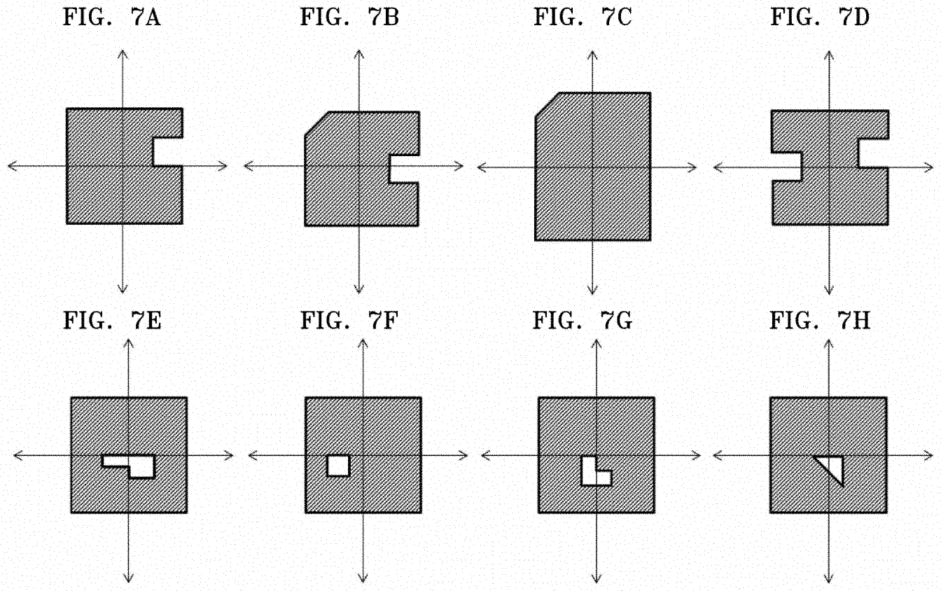

FIG. 8 is a perspective view showing a state in which bonding electrodes 41 and 42 are formed on the display substrate.

FIG. 9 is a perspective view showing a state in which a groove having the same shape as the symmetric LED element is formed in the display substrate.

FIG. 10 is a perspective view showing a state in which the symmetric LED element is inserted into the groove of the display substrate.

FIGS. 11A, 11B, and 11C are perspective views showing an asymmetric LED element.

FIG. 12 is a perspective view showing a state in which a groove having the same shape as the asymmetric LED element is formed in the display substrate.

FIG. 13 is a perspective view showing a state in which the asymmetric LED element (FIG. 11A) having one type of shape is aligned and inserted in the groove of the display substrate.

FIG. 14 shows a blue LED element (FIGS. 14A, 14D, and 14G), a green LED element (FIGS. 14B, 14E, and 14H), and a red LED element (FIGS. 14C, 14F, and 14I) required to constitute a full-color display device.

FIG. 15 is a perspective view showing a state in which grooves respectively having the same shapes as the asymmetric blue LED element (FIG. 14A), the asymmetric green LED element (FIG. 14B), and the asymmetric red LED element (FIG. 14C) are formed on the display substrate.

FIG. 16 is a perspective view showing states 301, 401, and 501 in which the asymmetric blue LED element (FIG. 14A), the asymmetric green LED element (FIG. 14B), and the asymmetric red LED element (FIG. 14C) are aligned and inserted in the grooves of the display substrate, respectively.

FIG. 17A is a perspective view showing an LED element having an asymmetric shape and formed by perforating a semiconductor layer, FIG. 17B is a perspective view showing a display substrate formed with a groove 101 having the same shape as the LED element, and FIG. 17C is a perspective view showing a state in which an LED element 601 (FIG. 17A) is aligned and inserted in the groove 101.

### MODE FOR INVENTION

### Best Mode

Hereinafter, the present invention will be described in detail with reference to the drawings.

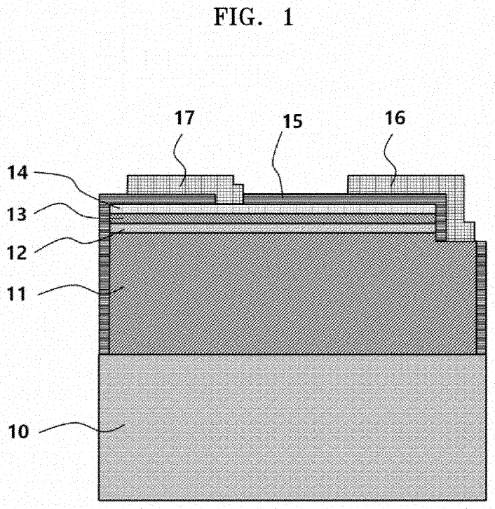

FIG. 1 is a sectional view showing a structure of an LED element to be used to implement a full-color LED display device.

Referring to FIG. 1, a sapphire substrate may be used as a growth substrate 10. In this case, the growth substrate may effectively withstand a high-temperature condition and the like, which are required when manufacturing the LED element, and the growth substrate refers to a substrate that assists epitaxial growth of a semiconductor layer. For example, sapphire, Si, SiC, MgAl₂O₄, MgO, LiAlO₂, LiGaO₂, GaN, glass, and GaAs substrates may be used as a semiconductor growth substrate.

Referring to FIG. 1, a first-conductivity type semiconductor layer 11, an active layer 12, and a second-conductivity type semiconductor layer 13 may be grown on the growth substrate 10 by using metal organic chemical vapor deposition (MOCVD). In order to form an LED element, first, dry etching may be performed to a level of a first semiconductor layer 11. Thereafter, a second semiconductor layer 13 and an ohmic contact layer 14 may be formed of a metal or a transparent conductive oxide. Thereafter, etching may be performed to a level of the growth substrate 10. At this time, the growth substrate may be partially etched. In this case, the LED element may be etched to have an asymmetric shape when viewed from an electrode side of the LED element or an opposite side of the electrode side. An electrical insulating film 15 may be formed in each LED element, the electrical insulating film 15 may be etched to a level of the ohmic contact layer 14 and the first semiconductor layer to form a contact hole, and bonding metal layers 16 and 17 may be formed.

In FIG. 1, n-GaN 11, the active layer 12, and p-GaN, which are semiconductor layers, may represent only the most essential layers of the element.

In FIG. 1, the bonding metal layer 17 may be electrically connected to the ohmic contact layer 14, and the bonding metal layer 16 may make ohmic contact with the first semiconductor layer. The bonding metal layers 16 and 17 may include an ohmic contact layer, an under bump metallurgy (UBM) layer, and a solder layer; the metal layer making ohmic contact with the first semiconductor may have a single-layer or multilayer structure formed of a material including at least one of a material such as Ti, Cr, Al, Ag, Rh, Ni, Cu, and a transparent conductive oxide, and an alloy thereof; the UBM layer may have a single-layer or multilayer structure formed of a material including at least one of a material such as Ti, Cr, Ni, Cu, Pd, and Ag, and an alloy thereof; and the solder layer may be formed of various chemical compositions including one or a plurality of metals among Sn, Ag, Cu, Ni, In, Bi, Zn, Al, Au, and Ga.

A photoresist (PR) may be coated onto the LED element to cover the LED element, and the PR may be bonded to another support substrate by using wax.

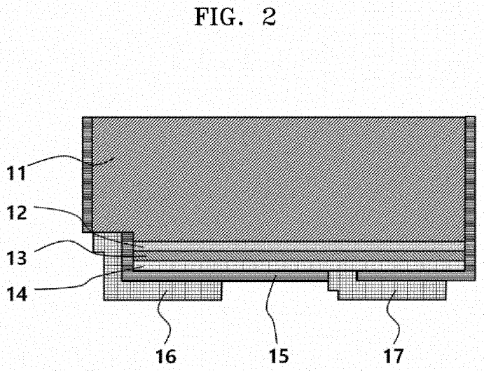

As shown in FIG. 2, the LED element may be separated from the growth substrate 10 by a laser lift off (LLO) scheme.

Depending on a type of the growth substrate, the growth substrate may be separated by a scheme such as laser lift off (LLO), chemical lift off (CLO), polishing, and dry etching.

After the LLO, a gallium molten droplet (Ga droplet) and foreign substances remaining on the semiconductor layer may be removed by using HCl. In order to further increase light extraction efficiency, a concavo-convex portion may be generally formed on an n-GaN surface by using KOH. Although not shown in the drawing, if undoped GaN is present under the n-GaN, KOH may be used to form a concavo-convex portion similarly to the above configuration. Since the electrical insulating film 15 of FIG. 1 connects the LED elements to each other, only the connected portion may be cut by the dry etching.

In addition, when the PR and the wax are removed, the LED elements of FIG. 2 may be separated. Then, the PR and the wax remaining on the LED element may be removed by using isopropyl alcohol (IPA) and deionized water (DI water), and moisture may be dried out. If the PR and the wax are not sufficiently removed, the PR and the wax may be additionally removed by a descum or asking scheme.

Another scheme is to attach the LED element to an UV tape, PDMS, or the like. Thereafter, the LED element and the growth substrate may be separated from each other by the LLO scheme, and the LED element may be separated from the UV tape or the PDMS.

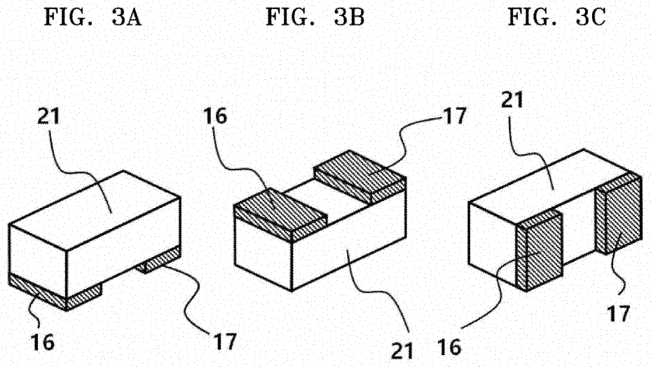

FIGS. 2 and 3 schematically show the LED element manufactured through the above processes.

A reference numeral 21 of FIG. 3, which includes all of reference numerals 11, 12, 13, 14, and 15 of FIG. 2, is schematically shown. The bonding metal layer of FIG. 3 may include the bonding metal layer 17 electrically connected to the second semiconductor layer and the bonding metal layer 16 electrically connected to the first semiconductor layer.

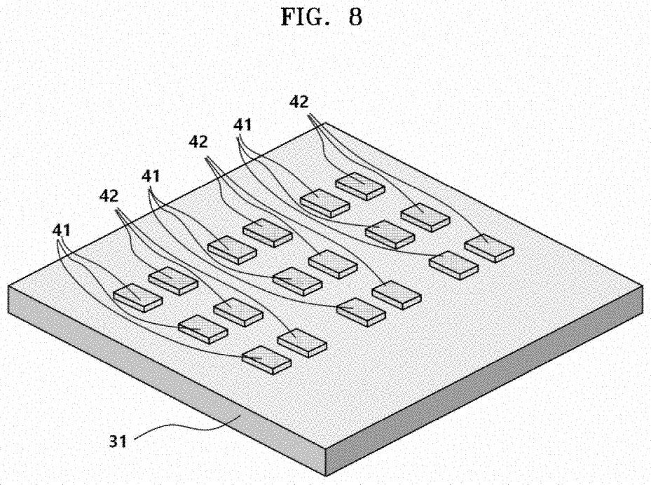

Reference numerals 41 and 42 of FIG. 8 represent a plurality of bonding electrodes which may bond the bonding electrodes 16 and 17 of the LED element to a display substrate 31 on which a thin film transistor (TFT) is formed. The bonding electrodes 41 and 42 may be connected to TFTs, respectively. The bonding electrodes 41 and 42 may have a typical under bump metallurgy (UBM) so that a solder material may excellently form an inter-metallic compound (IMC). A reference numeral 31 represents the display substrate including the TFT.

A groove having the same shape as the LED element may be formed so that the LED element may be aligned on the substrate in a predetermined direction by a physical force. The groove may have a suitable clearance so that the LED element may be inserted into the groove. Each groove may have a depth that allows only one LED element to be inserted into the groove.

The groove may be formed by applying a photosensitive material through coating in a photolithography scheme. Alternatively, glass, spin on glass (SOG), or a polymer material may be coated onto the display substrate, and the photosensitive material may be applied through the coating to form a pattern in the photolithography scheme. In addition, dry or wet etching may be performed, and the photosensitive material may be removed.

The technology of moving numerous LED elements to a desired position within a short time may take a long process time, or requires a facility capable of aligning the LED elements with high precision while placing the LED elements at the desired position. In addition, in most of the technologies, the LED elements arranged on the growth substrate may be transferred on the display substrate as they are. The present invention proposes a method of moving and bonding hundreds of thousands to millions of LED elements or more to a desired position. To achieve the above object, the LED elements have to be individually separated from each other, and the display substrate has to be formed with the groove having the same shape as the LED.

Sequentially, the display substrate may be fixedly placed on a mechanical device capable of applying a physical force such as vibration, rotation, and tilting, the LED element may be distributed on the display substrate, and the physical force may be applied by the mechanical device. As a result, the LED elements may be aligned and inserted in grooves, respectively.

FIG. 3 is a perspective view showing a symmetric LED element.

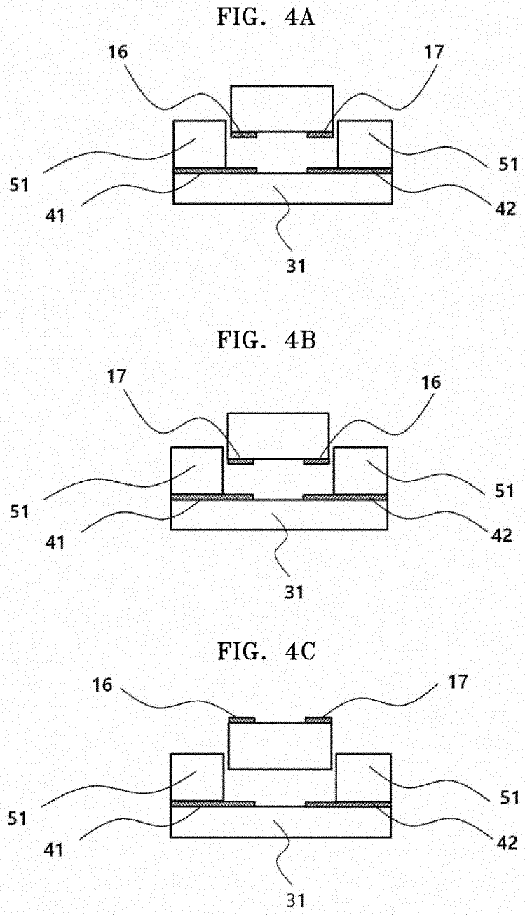

FIG. 4 is a plan view showing axisymmetric shapes.

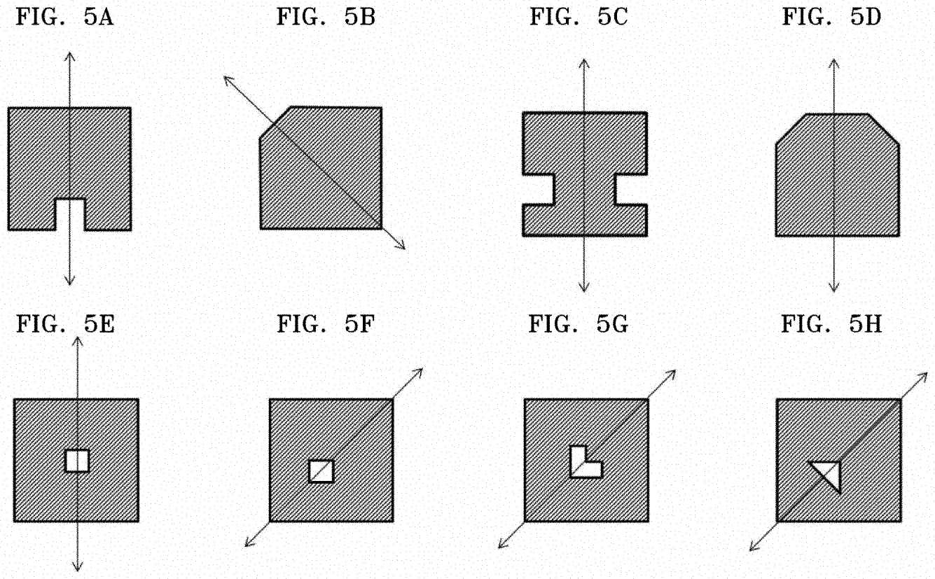

FIG. 5 is a plan view showing point-symmetric shapes.

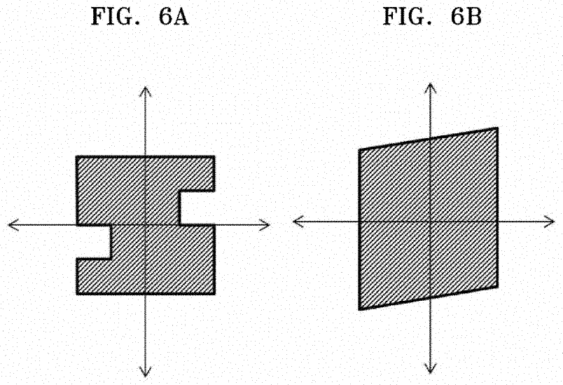

FIG. 6 is a plan view showing asymmetric shapes.

FIG. 4 is a sectional view showing a state in which the symmetric LED element is inserted into a groove on an LED substrate.

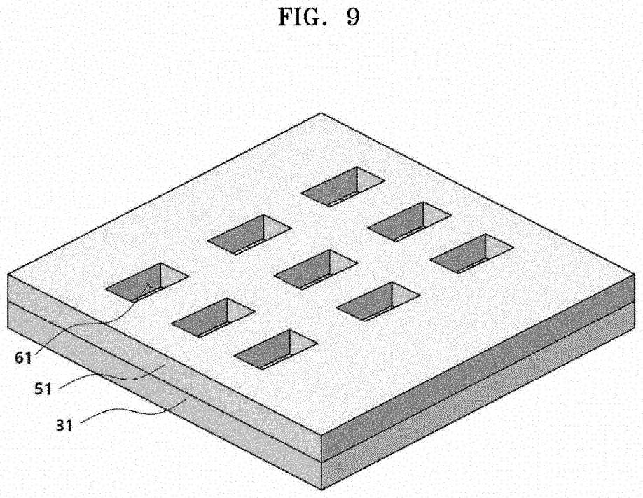

FIG. 9 is a perspective view showing a state in which a groove is patterned on a display substrate.

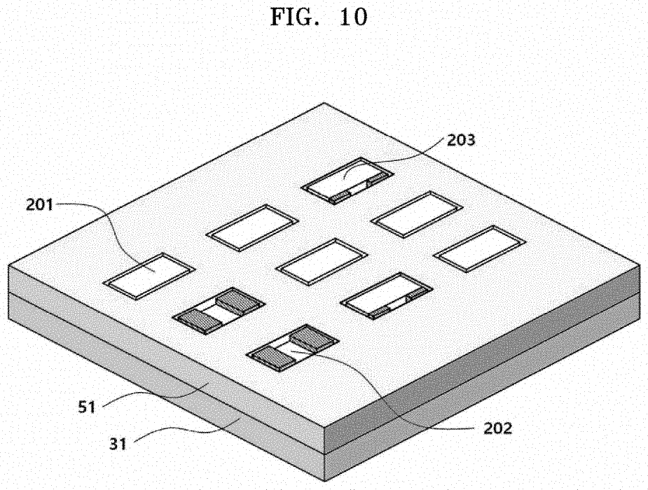

FIG. 10 is a perspective view showing a state in which the symmetric LED element is inserted into the groove of the display substrate.

Referring to FIGS. 3, 4, 9, and 10, if the LED element is formed to be symmetric when viewed from the electrode side or the opposite side thereof, there may be many cases such as a case where the LED elements are normally inserted into grooves, respectively, a case where a positive electrode and a negative electrode are inversely inserted, and a case where the element is inserted upside down.

Therefore, the LED element is manufactured to be asymmetric when viewed from the electrode side or the opposite side thereof. When the LED element has an asymmetric shape, the first bonding electrode 16 and the second bonding electrode 17 of the LED element may be aligned so as to be bonded to a first bonding electrode 41 and a second bonding electrode of the display substrate, respectively.

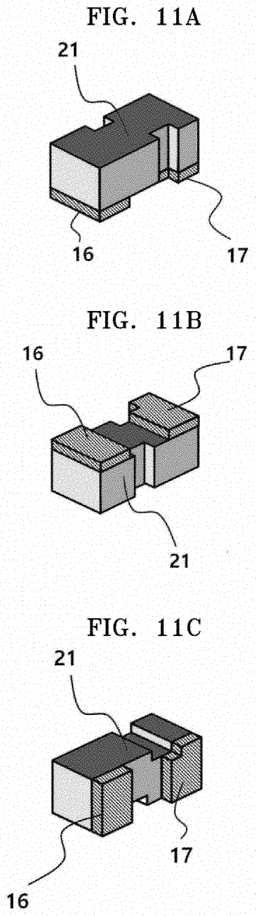

FIG. 11 is a perspective view showing an asymmetric LED element.

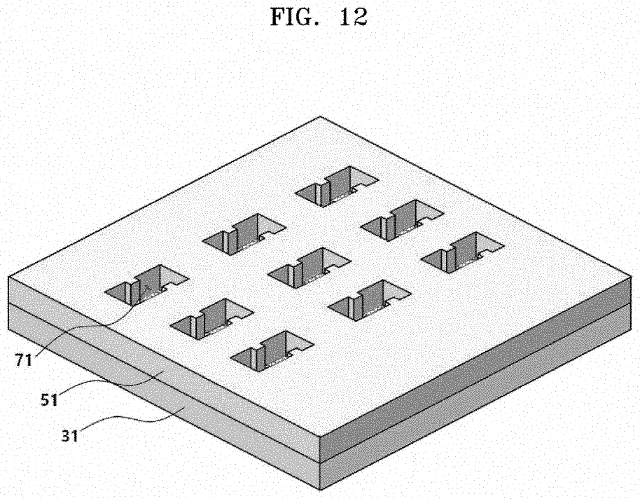

FIG. 12 is a perspective view showing a state in which a groove having the same shape as the asymmetric LED element is formed in the display substrate.

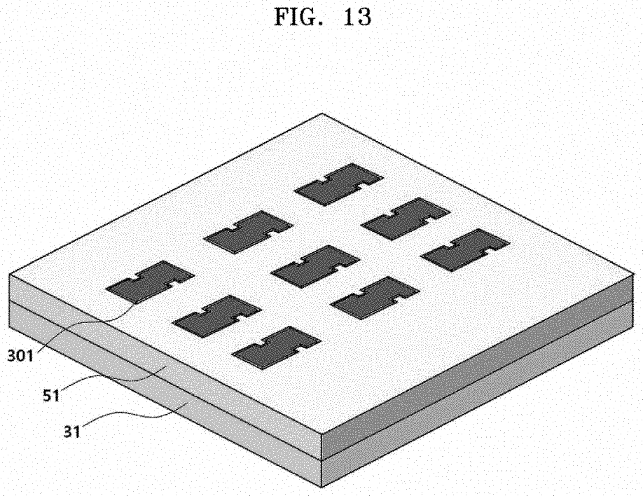

FIG. 13 is a perspective view showing a state in which the asymmetric LED element (FIG. 11A) having one type of shape is aligned and inserted in the groove of the display substrate.

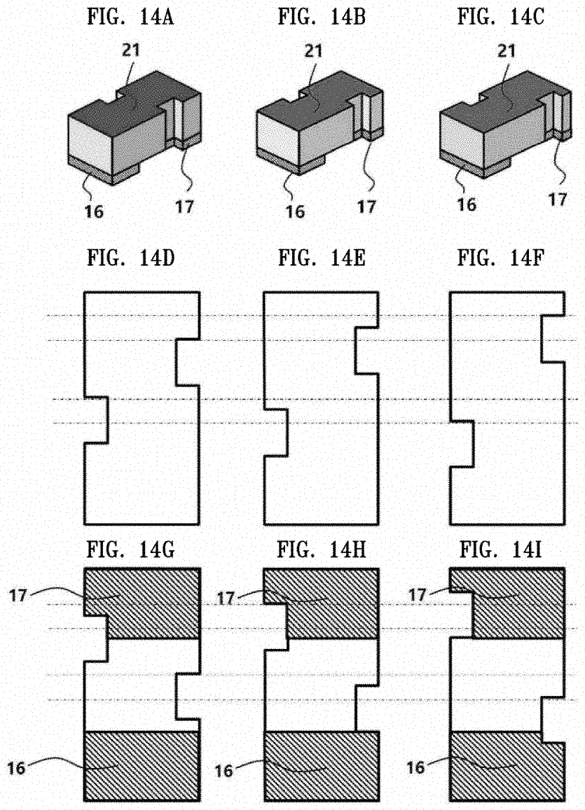

FIG. 14 shows a blue LED element (FIG. 14A), a green LED element (FIG. 14B), and a red LED element (FIG. 14C) required to constitute a full-color display device.

Referring to FIG. 14, the blue, green, and red LED elements may have asymmetric shapes which are slightly different from each other, and the shapes on the electrode sides (FIGS. 14D, 14E, and 14F) and the shapes on the opposite sides (FIGS. 14G, 14H, and 14I) of the blue, green, and red LED elements have to be different from each other. Grooves having shapes identical to the shapes of the opposite sides (FIGS. 14G, 14H, and 14I) of the electrode sides of the blue, green, and red LED elements may be formed on the display substrate on which the TFT is formed. The groove may have a clearance to allow the LED element to be inserted into the groove. As a result, the blue, green, and red LED elements may be aligned and inserted in the grooves that fit the shapes of the LED elements, respectively.

In more detail, for example, when the blue LED element and the green LED element have mutually different shapes when viewed from the electrode side while the shape viewed from the electrode side of the blue LED element is the same as the shape viewed from the opposite side of the electrode side of the green LED element, the green LED element may be aligned upside down such that the electrode faces upward in the groove of the substrate into which the blue LED element is to be inserted. Similarly, the blue LED element may be aligned upside down such that the electrode faces upward in the groove of the substrate into which the green LED element is to be inserted.

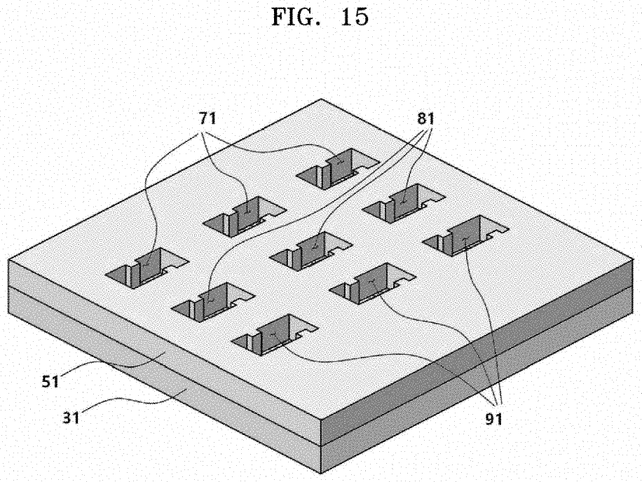

FIG. 15 is a perspective view showing a state in which grooves 71, 81, and 91 respectively having the same shapes as the asymmetric blue, green, and red LED elements are formed on the display substrate.

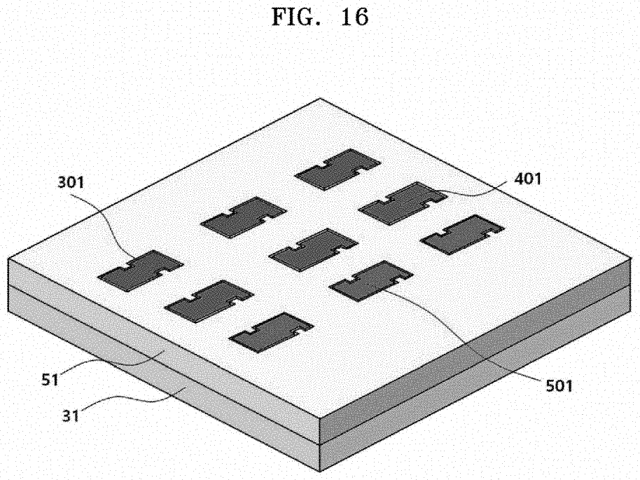

FIG. 16 is a perspective view showing states 301, 401, and 501 in which the asymmetric blue LED element (FIG. 14A), the asymmetric green LED element (FIG. 14B), and the asymmetric red LED element (FIG. 14C) are aligned and inserted in the grooves of the display substrate, respectively.

The blue, green, and red LED elements may be distributed on the display substrate formed with the grooves, which respectively have the same shapes as the LED elements, and the TFT such that the number of the blue, green, and red LED elements of which the number is larger than the number of the grooves in the substrate. The blue, green, and red LED elements may be distributed at a ratio that allows the numbers of the blue, green, and red LED elements to be similar to each other such that approximately an entire area of the substrate may be covered. When the LED elements are simply distributed, the probability of the LED elements being inserted into the grooves may be very low. Therefore, the present invention provides a method including: forming the LED element and the groove of the display substrate in asymmetric shapes; placing the display substrate on a plate that may be subjected to the physical force such as vibration, rotation, and tilting; and seating the LED element in the grooves, respectively.

The LED element may be located at the desired position as described above, and the display substrate may be reflowed so that a solder provided on a surface of the LED element or a solder provided on the electrode of the display substrate may be melted.

In addition, when the reflow is performed, press-bonding may be performed by using a pressing roll so that the LED element and the display substrate may be excellently bonded to each other.

In order to prevent the moisture from penetrating into the LED element, a front surface of the display substrate to which the LED element is bonded may be coated.

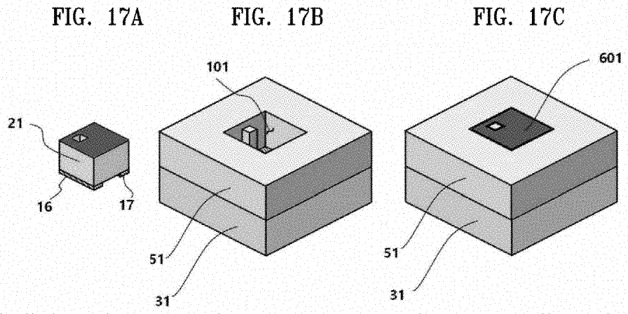

In FIG. 17, FIG. 17A is a perspective view showing an LED element having an asymmetric shape and formed by perforating a semiconductor layer, FIG. 17B is a perspective view showing a display substrate formed with a groove 101 having the same shape as the LED element, and FIG. 17C is a perspective view showing a state in which an LED element 601 (FIG. 17A) is aligned and inserted in the groove 101.

### INDUSTRIAL APPLICABILITY

The full-color LED display device and the method for manufacturing the same according to the present invention can be widely used in the display industry.

1. A method for manufacturing an LED display device, the method comprising:
growing a semiconductor layer on a growth substrate;
forming a plurality of LED elements, which are asymmetric with mutually different shapes and in which the semiconductor layer is separated;
separating the LED elements from the growth substrate;
forming a bonding electrode, to which the LED element is bonded, on a display substrate including a thin film transistor (TFT);
forming a groove on the display substrate by patterning the display substrate in a shape identical to the shape of the LED elements which are asymmetric;
seating the LED element in a pattern, which has the groove having a shape identical to the shape of the LED element, by a physical force; and
establishing electrical connection by the bonding electrode of the display substrate or an adhesive conductive material formed on a bonding electrode of the LED element.

2. The method of claim 1, wherein the growth substrate includes a material selected from the group consisting of sapphire, Si, SiC, MgAl₂O₄, MgO, LiAlO₂, LiGaO₂, GaN, glass, and GaAs.

3. The method of claim 1, further comprising:
etching to a level of a first semiconductor layer;
forming a second semiconductor layer and an ohmic contact layer by using a metal or a transparent conductive oxide;
etching the semiconductor layer to a level of the growth substrate to form the LED element in an asymmetric shape;
depositing an insulating layer on a surface of the LED element in which an electrode is formed and on a side surface of the LED element;
etching a portion of an insulator to a level of the ohmic contact layer of the second semiconductor layer and the first semiconductor layer;
forming a second bonding electrode electrically connected to the ohmic contact layer of the second semiconductor layer and a first bonding electrode making ohmic contact with the first semiconductor layer; and
separating the growth substrate and the LED element from each other.

4. The method of claim 1, wherein when etching the semiconductor layer to a level of the growth substrate, the LED element has an asymmetric shape such that a shape of the LED element viewed from a bonding electrode side or an opposite side of the bonding electrode side is asymmetric.

5. The method of claim 3, wherein the insulating layer includes a material selected from the group consisting of SiO₂, SiN, TiO₂, Si₃N₄, Al₂O₃, TiN, AlN, ZrO₂, TiAlN, and TiSiN.

6. The method of claim 3, wherein the second bonding electrode and the first bonding electrode of the LED element bonded to the display substrate include an ohmic contact layer, an under bump metallurgy (UBM) layer, and a solder layer,
the ohmic contact layer on a first semiconductor includes a material selected from the group consisting of Ti, Cr, Al, Ag, Rh, Ni, Cu, and a transparent conductive oxide,
the UBM layer includes a material selected from the group consisting of Ti, Cr, Ni, Cu, Pd, and Ag, and
the solder layer includes a material selected from the group consisting of Sn, Ag, Cu, Ni, In, Bi, Zn, Al, Au, and Ga.

7. The method of claim 1, further comprising:
coating a photoresist onto the LED element formed on the growth substrate, baking the photoresist, and wax-bonding the photoresist to a support substrate; or
bonding the LED element formed on the growth substrate to an adhesive UV tape or polydimethylsiloxane (PDMS).

8. The method of claim 1, further comprising separating the semiconductor layer and the growth substrate from each other,
wherein the growth substrate is removed through laser lift off (LLO), chemical lift off (CLO), or dry etching.

9. The method of claim 1, further comprising removing a foreign substance, which remains after separating the semiconductor layer and the growth substrate from each other, by using HCl.

10. The method of claim 1, further comprising providing a surface concavo-convex portion to a surface of the semiconductor layer separated from the growth substrate by using KOH.

11. The method of claim 3, further comprising etching a portion of the insulator layer from the semiconductor layer and the insulator layer which are exposed after being separated from the growth substrate.

12. The method of claim 1, further comprising:
separating the LED element from a support substrate by using a photoresist remover to individually separate the LED elements disposed on the support substrate; or
separating the LED element bonded to the adhesive UV tape or the PDMS.

13. The method of claim 1, wherein the display substrate includes glass, a semiconductor substrate, or a flexible polymer material.

14. The method of claim 1, further comprising:
forming the bonding electrode, which respectively bonds a plurality of TFTs to the LED elements through an electrical wire, on the display substrate; and
forming the groove having the shape identical to the shape of the LED element, which is asymmetric and has the bonding electrode that is exposed.

15. The method of claim 1, wherein when the LED element is inserted into the groove, a clearance is formed between the groove and the LED element.

16. The method of claim 1, wherein the groove is formed by applying a photosensitive material and patterning the photosensitive material through photolithography, or formed by applying glass, spin on glass (SOG), silicon, or a polymer material through coating, and patterning the glass, the SOG, the silicon, or the polymer material.

17. The method of claim 1, wherein the groove is formed by using a mask having a hole which has a shape identical to the shape of the LED element.

18. The method of claim 1, wherein the seating of the LED element in the pattern, which has the groove having the shape identical to the shape of the LED element, by the physical force includes:
distributing the LED elements, which are individually separated, on the display substrate having the groove;
applying the physical force of vibration, rotation, or tilting to the display substrate;
inserting and aligning the LED element in the groove; and
separating remaining LED elements, which are not inserted into the groove, from the display substrate.

19. The method of claim 1, further comprising establishing the electrical connection by applying heat or a pressure onto the bonding electrode of the display substrate or the adhesive conductive material formed on the bonding electrode of the LED element.

20. The method of claim 1, wherein after the LED element is bonded to the display substrate, a pattern material for forming the groove is removed or left.
